(19) United States
(12) Patent Application Publication
(10) Pub. No.: US 2012/0168825 A1
(43) Pub. Date: Jul. 5, 2012

(54) Charged Coupled Device Module and Method of Manufacturing the Same

(75) Inventor: Tzu-Chih Lin, Qionglin Township (TW)

(73) Assignee: ALTEK CORPORATION, Hsinchu (TW)

(21) Appl. No.: 13/150,577

(22) Filed: Jun. 1, 2011

(30) Foreign Application Priority Data
Dec. 31, 2010 (TW) 099147423

(51) Int. Cl. H01L 31/0232; H01L 31/18

(52) U.S. Cl. 257/225; 438/65; 257/E31.11

(57) ABSTRACT

A charged coupled device (CCD) module fixed between a lens assembly and a main board having a first plate surface is disclosed. The CCD module comprises a hard PCB having a first surface and a second surface, a CCD component, and at least one fixed member. The first surface of the hard PCB faces the first plate surface of the main board. The CCD component facing the lens assembly is located on the second surface of the hard PCB. The fixed member is used for combining the hard PCB and the main board. The hard PCB and the fixed member can be used as a buffer to reduce possible damages to the CCD component and/or the main board.

### BACKGROUND OF THE INVENTION

1. Field of the Invention

The present invention relates to a charge coupled device (CCD) module and a manufacturing method of the CCD module, particularly to a CCD module and a manufacturing method of the CCD module for improving the connection of the CCD module with a main board.

2. Description of the Related Art

With reference to FIG. 1 for an exploded view of a conventional lens module of an imaging device, the lens module 10 at least comprises a lens assembly 11, a CCD module 12 and a main board 14. During assembling, the CCD module 12 is fixed (or secured) onto the lens assembly 11, and then surface mount technology (SMT) or dual in-line package (DIP) is used for fixing pins (not shown in the figure) of the CCD module 12 to the main board 14.

Since the CCD module 12 should be calibrated before it is fixed to the lens assembly 11, a deviation and/or a gap may be formed between the CCD module 12 and the main board 14. When the CCD module 12 is secured to the main board 14, the main board 14 fixed with other components (not shown in the figure) may be deformed, and a break or crack may occur between the pins (not shown in the figure) of the CCD module 12 and the main board 14, and the electric connection may be affected adversely. Therefore, it is necessary to provide novel improved CCD module and manufacturing method of the CCD module to overcome the aforementioned problems.

### SUMMARY OF THE INVENTION

It is a primary objective of the invention to overcome the shortcomings of the prior art by providing a CCD module fixed between a lens assembly and a main board, and the main board includes a first plate surface. The CCD module comprises a hard PCB, a CCD component and at least one fixing member. The hard PCB has a first surface and a second surface, wherein the first surface faces the first plate surface. The CCD component is disposed on the second surface and faces the lens assembly, and the fixing member is provided for coupling the hard PCB and the main board. The hard PCB and the fixing member can be used as buffers between the CCD component and the main board to reduce possible damages to the CCD component and/or the main board.

In the CCD module in accordance with a first preferred embodiment of the present invention, the fixing member includes a plurality of positioning pillars and a plurality of hot-melt metals. The positioning pillars are disposed on the first surface of the hard PCB. Preferably, the positioning pillars are disposed around the periphery of the first surface of the hard PCB. The main board includes a plurality of first penetrating holes corresponding to the positioning pillars, and the positioning pillars are disposed in the first penetrating holes respectively, and the positioning pillars and the first penetrating holes are melted and coupled through a plurality of hot-melt metals in order to dispose the CCD module on the main board.

Compared with the prior art, the CCD module of the present invention is fixed to the lens assembly (not shown in the figure), and then the plurality of positioning pillars and the first penetrating holes of the main board are used for calibrating or correcting a deviation and/or a gap, and finally the positioning pillars and the first penetrating holes are melted and coupled by the plurality of hot-melt metals to overcome the problem of breaking or cracking the pins due to the deformation of the main board of the prior art.

The present invention further provides a CCD module in accordance with a second preferred embodiment, and the manufacturing method of the CCD module in accordance with the first and second preferred embodiments are described as follows.

### BRIEF DESCRIPTION OF THE DRAWINGS

FIG. 1 is an exploded view of a conventional lens module of an imaging device;

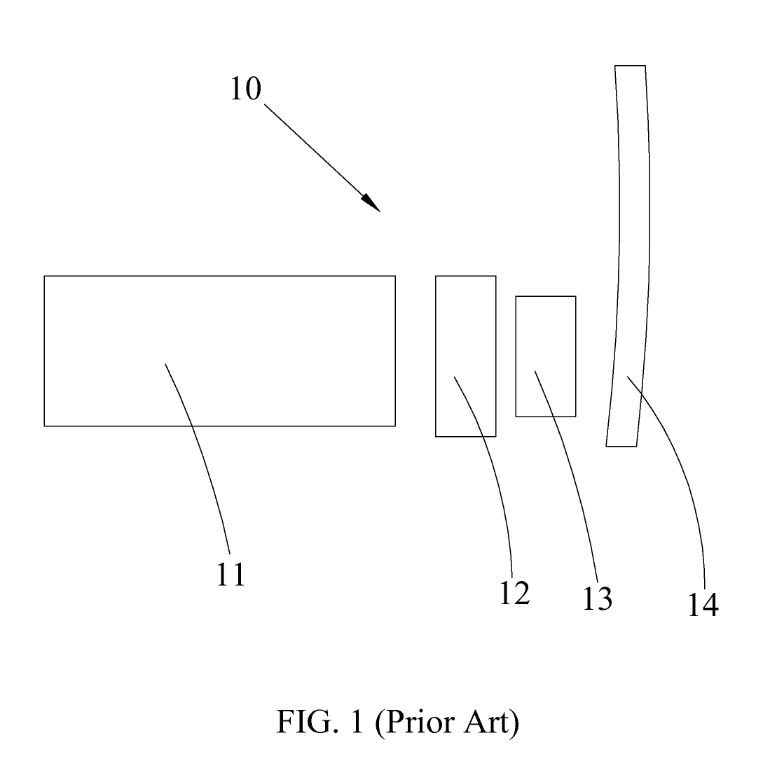

FIG. 2 is a schematic view of a CCD module according to the present invention;

FIG. 3A is a schematic view of a CCD module according to a first preferred embodiment of the present invention;

FIG. 3B is a partial enlargement view of FIG. 3A;

FIG. 3C is a perspective view of a CCD module as shown in FIG. 3A and coupled to a main board;

FIG. 4A is a schematic view of a CCD module according to a second preferred embodiment of the present invention;

FIG. 4B is a perspective view of a CCD module as depicted in FIG. 4A and coupled to a main board;

FIG. 5A is a flow chart of manufacturing a CCD module according to a first preferred embodiment of the present invention;

FIG. 5B is a schematic view of assembling a CCD module manufactured according to the flow chart as depicted in FIG. 5A and a plurality of positioning pillars;

FIG. 6A is a flow chart of manufacturing a CCD module according to the second preferred embodiment of the present invention; and

FIG. 6B is a schematic view of assembling a CCD module manufactured according to the flow chart as depicted in FIG. 6A and a main board.

### DETAILED DESCRIPTION OF THE PREFERRED EMBODIMENTS

To make it easier for our examiner to understand the technical contents of the present invention, preferred embodiments together with related drawings are used for the detailed description of the present invention. It is noteworthy to point out that same numerals are used for representing respective elements in the drawings respectively, and the drawings are provided for illustrating the technical characteristics of the present invention but not necessarily drawn according to the actual scale or practical applications.

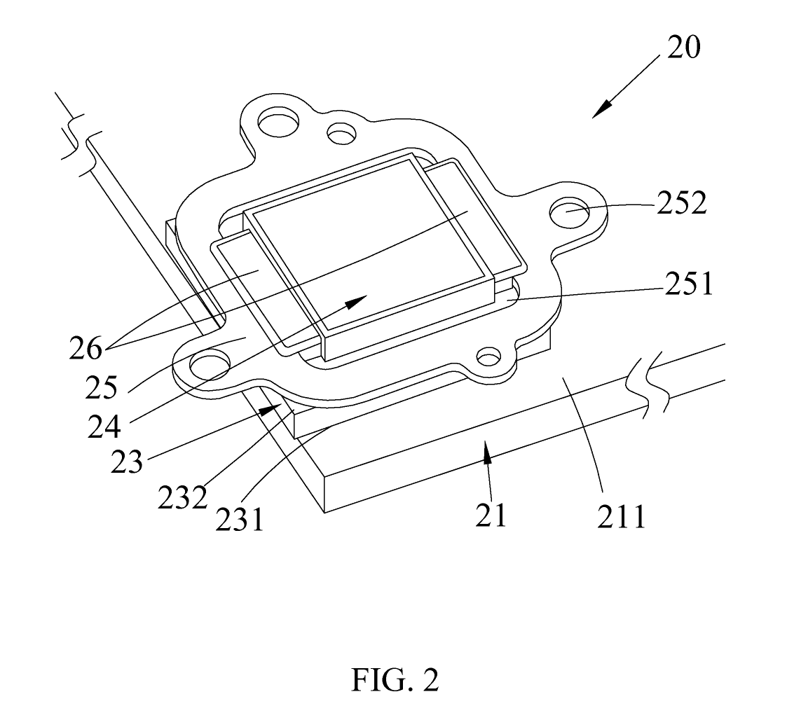

With reference to FIG. 2 for a schematic view of a CCD module of the present invention, the CCD module 20 is fixed between a lens assembly (not shown in the figure) and a main board 21, wherein the main board 21 includes a first plate surface 211.

The CCD module 20 of the present invention comprises a hard PCB 23 and a CCD component 24, wherein the hard PCB 23 has a first surface 231 and a second surface 232, and the first surface 231 of the hard PCB 23 faces the first plate surface 211 of the main board 21, and the CCD component 24 is disposed on the second surface 232 of the hard PCB 23 and faces the lens assembly (not shown in the figure).

The way of fixing the CCD module 20 of the present invention to a lens assembly (not shown in the figure) is described as follows. The CCD module 20 further comprises a CCD supporting board 25 and a first glue 26. The CCD supporting board 25 has an opening 251; the CCD supporting board 25 and the CCD component 24 are disposed on the second surface 232 of the hard PCB 23, wherein the opening 251 of the CCD supporting board 25 can accommodate the CCD component 24. After the relative positions of the CCD component 24 and the CCD supporting board 25 are calibrated, a first glue 26 is applied to bind the CCD supporting board 25, CCD component 24 and hard PCB 23 to fix the CCD supporting board 25, CCD component 24 and hard PCB 23, so as to produce the CCD module 20. The first glue 26 can be an UV glue, or any other equivalent curable material for fixing the CCD supporting board 25, CCD component 24 and hard PCB 23.

A screw (not shown in the figure) is passed into a positioning hole 252 of the CCD supporting board 25 to secure the CCD module 20 to the lens assembly (not shown in the figure). In other preferred embodiments of the present invention, methods such as latching, soldering, riveting, and binding can be used to fix the CCD module to the lens assembly (not shown in the figure).

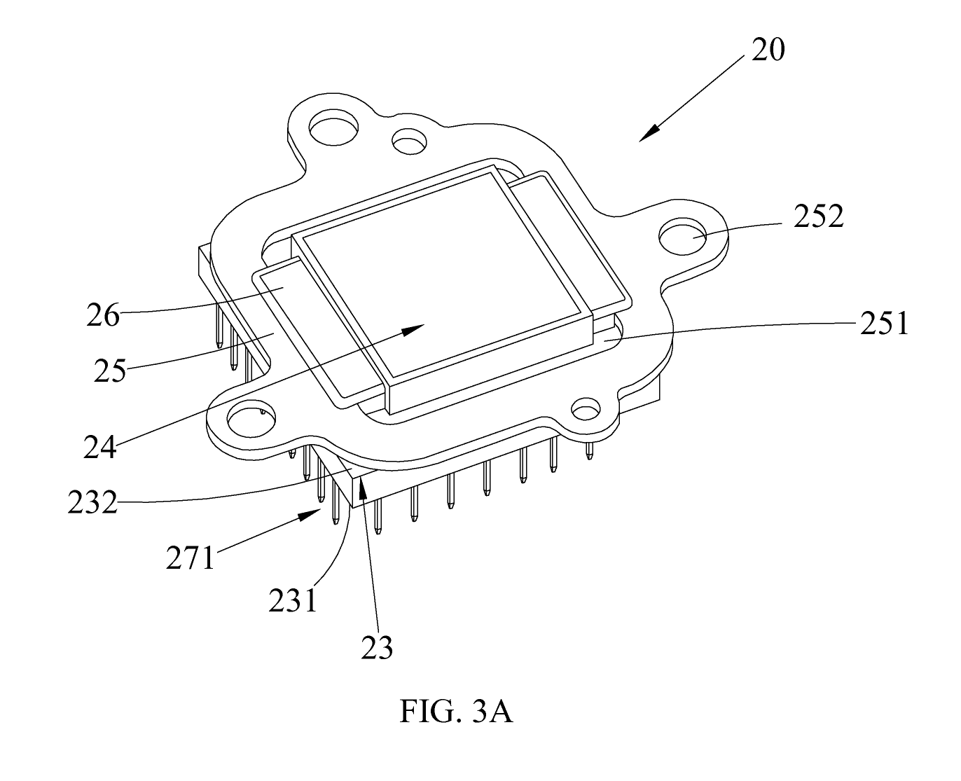

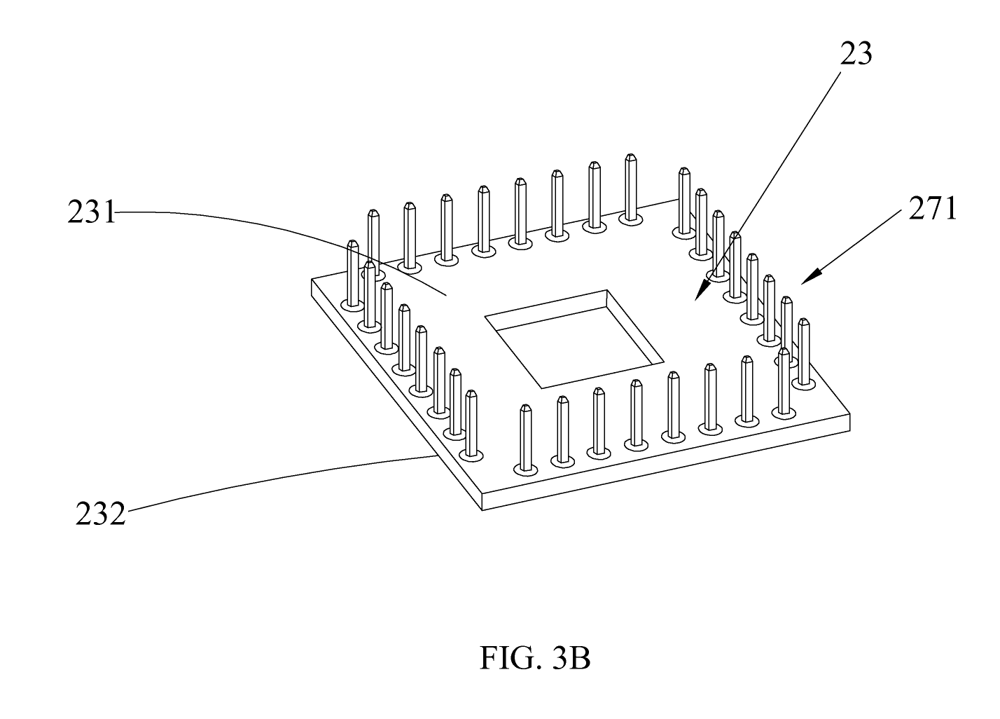

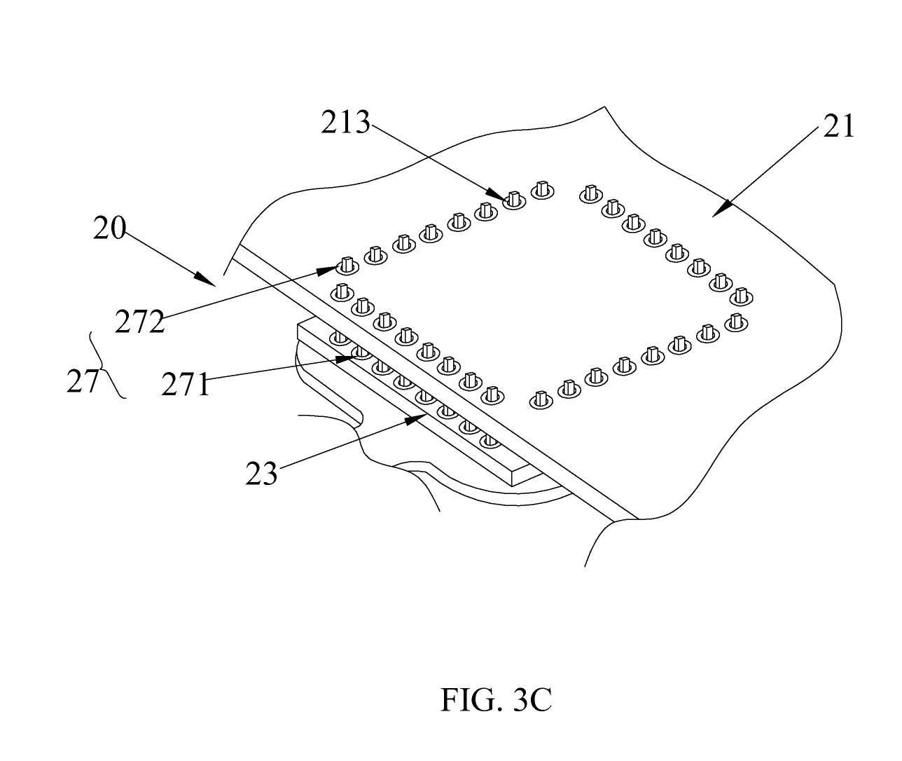

The way of fixing the CCD module 20 onto the main board 21 is described as follows. With reference to FIGS. 3A, 3B and 3C, FIG. 3A shows a schematic view of a CCD module in accordance with the first preferred embodiment of the present invention, FIG. 3B shows a partial enlargement view of FIG. 3A, and FIG. 3C shows a perspective view of coupling the CCD module as depicted in FIG. 3A to the main board. The CCD module 20 further comprises a fixing member 27, and the fixing member 27 comprises a plurality of positioning pillars 271 and a plurality of hot-melt metals 272. The positioning pillars 271 are disposed on the first surface 231 of the hard PCB 23, and the positioning pillars 271 are preferably disposed around the periphery of the first surface 231 of the hard PCB 23.

The main board 21 has a plurality of first penetrating holes 213 corresponding to the positioning pillars 271, such that the positioning pillars 271 can be disposed in the first penetrating holes 213 respectively. The positioning pillars 271 and the first penetrating holes 213 are melted and coupled by the plurality of hot-melt metals 272 in order to dispose the CCD module 20 onto the main board 21, wherein the positioning pillars 271 can be made of an electrically conductive material (such as a metal), and the hot-melt metal 272 can be a common soldering metal such as tin and copper used for electrically coupling the CCD module 20 and the main board 21.

Compared with the prior art, after the CCD module 20 of the present invention is fixed to the lens assembly (not shown in the figure), a possible deviation and/or gap occurred between the plurality of positioning pillars 271 and the first penetrating holes 213 of the main board 21 is calibrated or corrected, and then the positioning pillars 271 and the first penetrating holes 213 are melted and coupled by the plurality of hot-melt metals 272 to overcome the problem of breaking the pins due to the deformation of the main board in the prior art. In other words, the hard PCB 23 and the fixing member 27 (such as the plurality of positioning pillars 271 and the plurality of hot-melt metals 272) of the present invention act as buffers between the CCD component 24 and the main board 21 to reduce possible damages to the CCD component 24 and/or the main board 21.

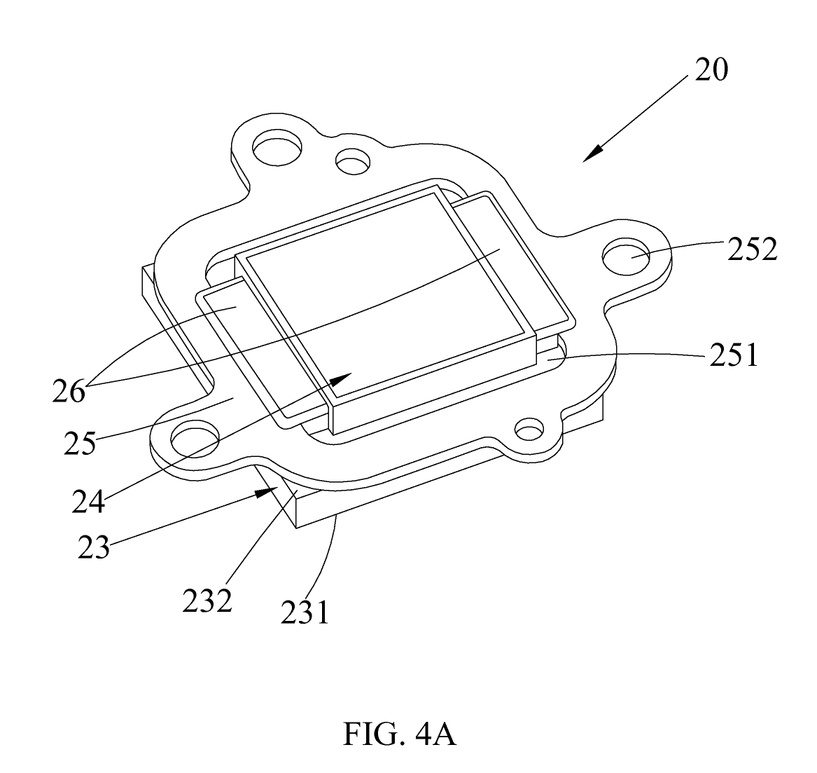

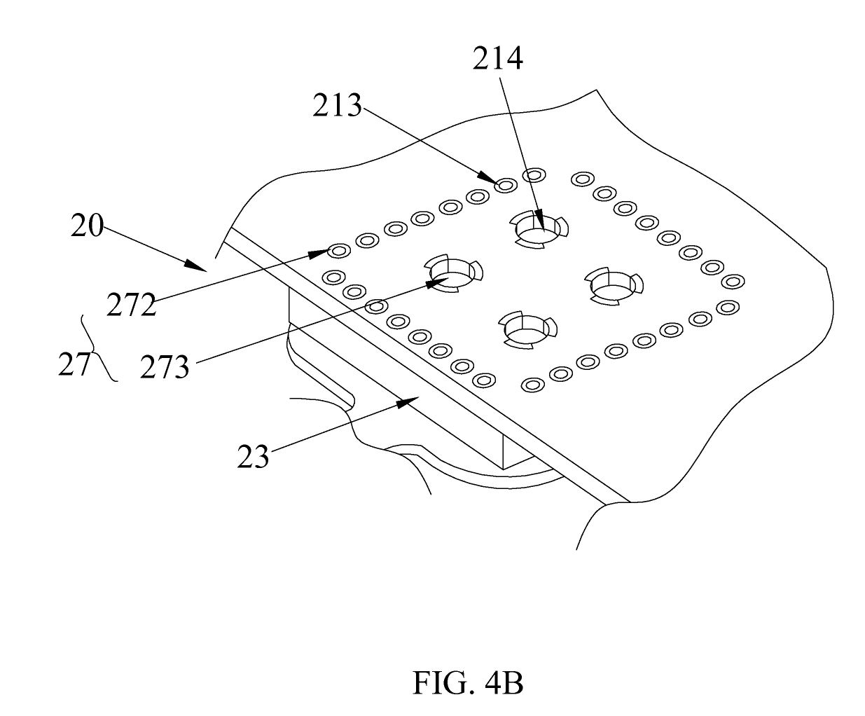

Another way of fixing the CCD module 20 onto the main board 21 is described as follows. With reference to FIGS. 4A and 4B, FIG. 4A shows a schematic view of a CCD module in accordance with a second preferred embodiment of the present invention, and FIG. 4B shows a schematic view of coupling the CCD module as depicted in FIG. 4A to the main board. The CCD module 20 further comprises a fixing member 27, and the fixing member 27 includes a plurality of hot-melt metals 272, and the main board 21 has a plurality of first penetrating holes 213, wherein the hot-melt metals 272 are placed on/into each first penetrating hole 213, and at least one hot spray nozzle (which will be described below) is provided for introducing hot air into the first penetrating holes 213, such that the first penetrating holes 213 and the first surface 231 of the hard PCB 23 are hot-melted and coupled by the hot-melt metals 272 to dispose the CCD module 20 onto the main board 21, wherein the hot-melt metal 272 can be a common soldering metal such as tin and copper and provided for electrically coupling the CCD module 20 and the main board 21.

Preferably, the fixing member 27 further comprises a plurality of second glues 273, and the main board 21 has a plurality of second penetrating holes 214. The second glues 273 bind the second penetrating holes 214 with the first surface 231 of the hard PCB 23. By this settlement, CCD module 20 and the main board 21 can be fixed more securely in the present invention. The material of the second glue 273 is not limited, such as an UV glue, tin, copper; any equivalent curable material that is able to fix two objects should be in the domain of the second glue 273 of the present invention.

In the present invention, the hard PCB 23 and the fixing member 27 (such as the plurality of hot-melt metals 272 and/or the second glue 273) act as buffers between the CCD component 24 and the main board 21 to reduce possible damages to the CCD component 24 and/or the main board 21. Compared with the CCD module of the first preferred embodiment of the present invention, the CCD module of this preferred embodiment does not require any positioning pillar, but a hot spray nozzle is used for binding the CCD module to the main board quickly. Therefore, the present invention has the advantages of a simple and quick manufacturing process and a low cost.

The manufacturing method of the CCD module in accordance with the present invention is described as follows. The architecture, structure, installation, material, scope and advantages of the CCD module (or the lens assembly and the main board) of the present invention are the same or similar to those of the previous preferred embodiment, and thus they will not be described here again. It is noteworthy out that the steps of the manufacturing method of the CCD module in accordance to a preferred embodiment are provided for the purpose of illustrating the invention only, and thus the sequence of the steps may vary, and not all steps or related elements/sub-steps must be adopted in the method.

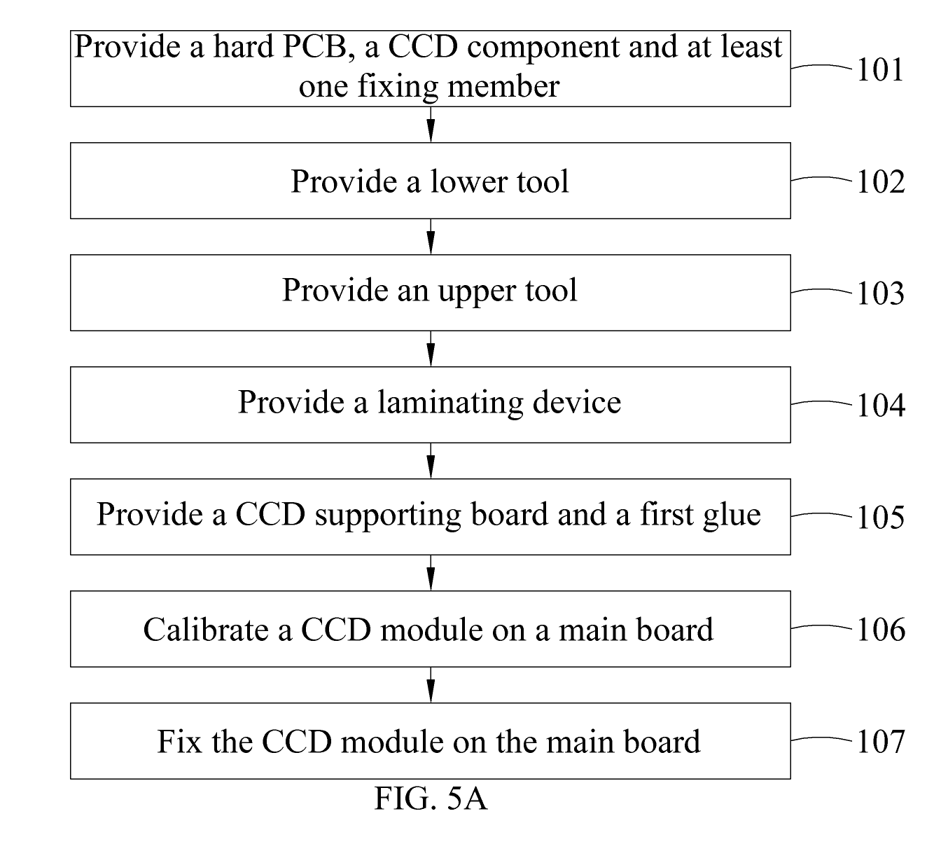

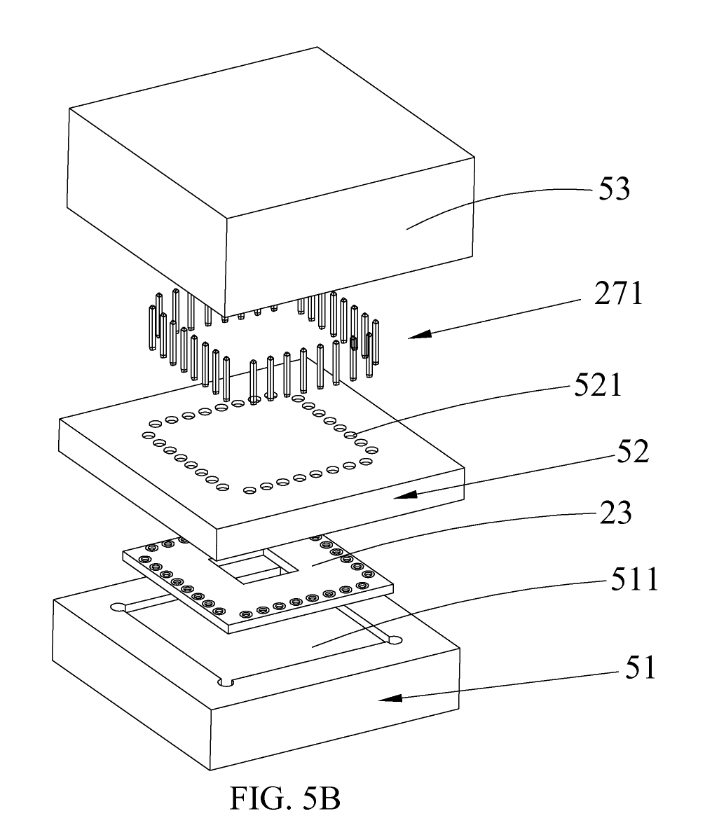

With reference to FIGS. 5A and 5B, FIG. 5A shows a flow chart of manufacturing a CCD module of a first preferred embodiment of the present invention, and FIG. 5B shows a schematic view of assembling a hard PCB and a plurality of positioning pillars during the manufacturing procedure as depicted in FIG. 5A. Please also refer to FIGS. 3A-3C.

Step 1 (101): Provide a hard PCB 23, a CCD component 24 and at least one fixing member 27.

Step 2 (102): Provide a lower tool 51. The lower tool 51 has a groove 511 for accommodating the hard PCB 23 and positioning the hard PCB 23 on the lower tool 51.

Step 3 (103): Provide an upper tool 52. The upper tool 52 is disposed above the lower tool 51, wherein the upper tool 52 has a plurality of through holes 521, and the positioning pillars 271 are disposed in the plurality of through holes 521 respectively, and each through hole 521 has a diameter slightly greater than the diameter of each positioning pillar 271.

Step 4 (104): Provide a laminating device 53. After the lower tool 51, the hard PCB 23, the upper tool 52, and the positioning pillars 271 disposed in the through holes 521 of the upper tool 52 are laminated, the positioning pillars 271 are protruded from the top of upper tool 52, and the laminating device 53 is used for laminating the positioning pillars 271 onto the first surface 231 of the hard PCB 23 in order to dispose the positioning pillars 271 onto the hard PCB 23, wherein the laminating device 53 can be a punching head, and a punching method is used for riveting the positioning pillars 271 onto the hard PCB 23. The present invention is not limited to such arrangement only, but any equivalent method of using the laminating device 53 to dispose the positioning pillars 271 onto the hard PCB 23 and its implementation are covered within the scope of the present invention.

Step 5 (105): Provide a CCD supporting board 25 and a first glue 26. The CCD supporting board 25 has an opening 251, and the CCD supporting board 25 and the CCD component 24 are disposed on the second surface 232 of the hard PCB 23, wherein the opening 251 of the CCD supporting board 25 can accommodate the CCD component 24. After the relative positions of the CCD component 24 and the CCD supporting board 25 are calibrated, the first glue 26 is applied among the CCD supporting board 25, CCD component 24 and hard PCB 23 to fix the CCD supporting board 25, CCD component 24 and hard PCB 23 in order to produce the CCD module 20. A screw (not shown in the figure) is passed into the positioning hole 252 of the CCD supporting board 25 to secure the CCD module 20 onto the lens assembly (not shown in the figure).

Step 6 (106): Calibrate the CCD module 20 on the main board 21. The fixing members 27 include a plurality of hot-melt metals 272, and the main board 21 has a plurality of first penetrating holes 213, and the first penetrating holes 213 are corresponsive to the positioning pillars 271, and the positioning pillars 271 are disposed in the first penetrating holes 213 respectively. A deviation and/or a gap can be calibrated and corrected by means of the plurality of positioning pillars 271 and the first penetrating hole 213 of the main board 21.

Step 7 (107): Fix the CCD module 20 on the main board 21, wherein the positioning pillars 271 and the first penetrating holes 213 are hot-melted and coupled by the hot-melt metals 272, such that the drawback of breaking the pins easily due to the deformation of the main board can be overcome. In other words, the hard PCB 23 and the fixing member 27 (such as the plurality of positioning pillars 271 and the plurality of hot-melt metals 272) act as buffers between the CCD component 24 and the main board 21 to reduce possible damages to the CCD component 24 and/or the main board 21.

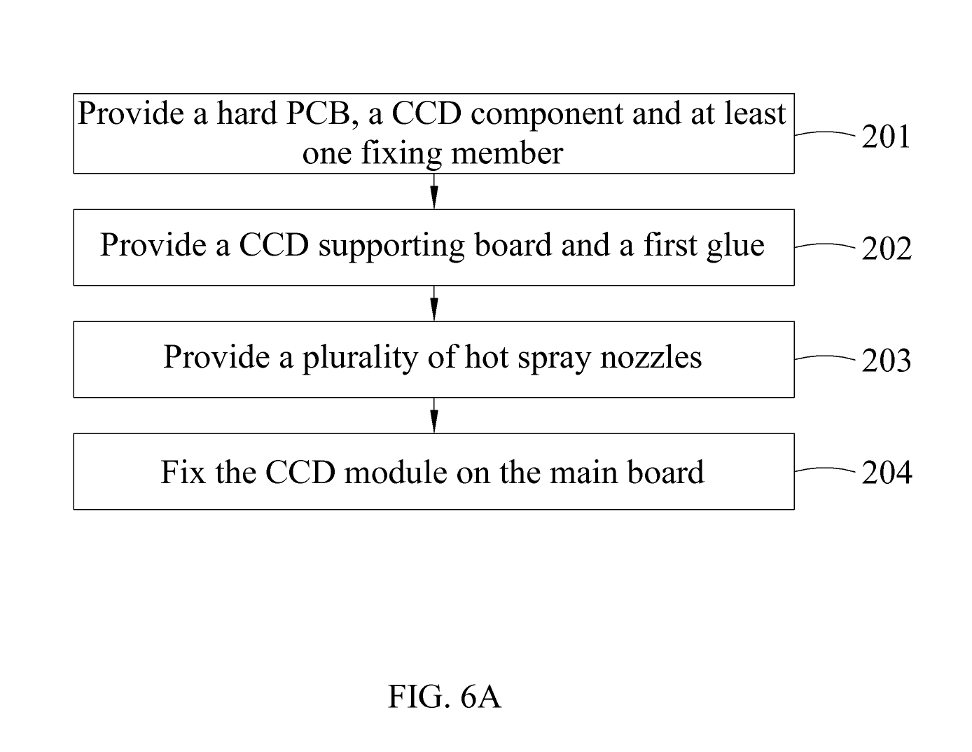

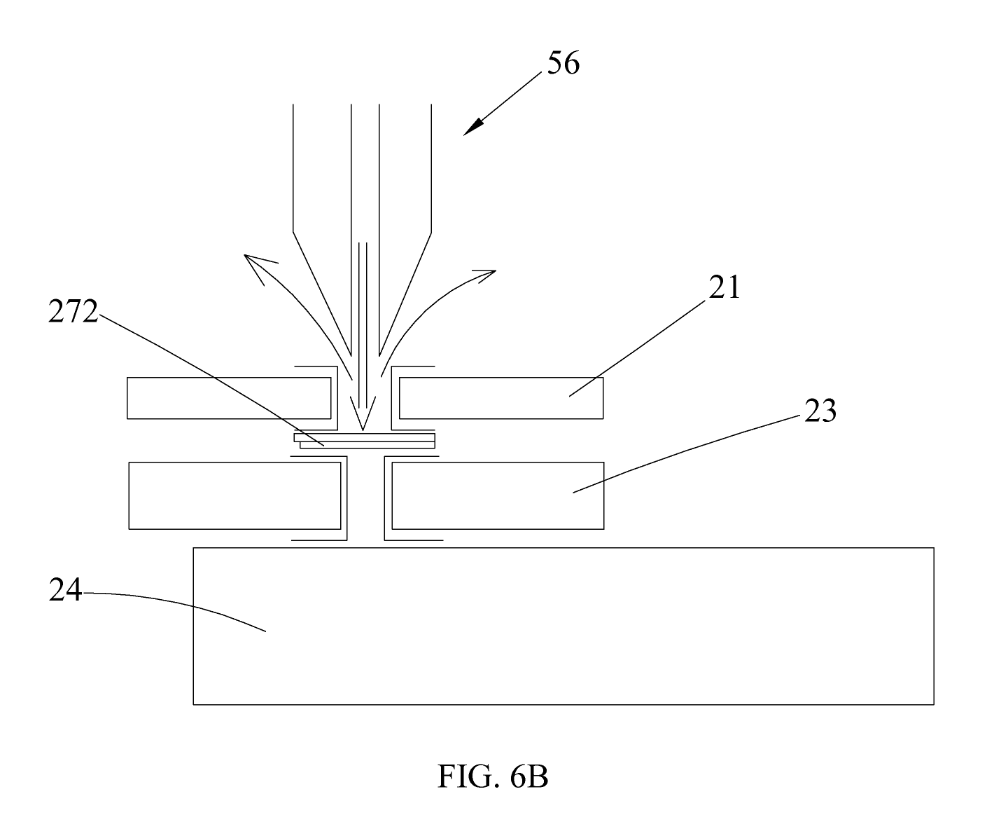

With reference to FIGS. 6A and 6B, FIG. 6A shows a flow chart of manufacturing a CCD module in accordance with a second preferred embodiment of the present invention, and FIG. 6B shows a schematic view of assembling the CCD module and the main board in the manufacturing procedure as depicted in FIG. 6A. Please also refer to FIGS. 4A and 4B.

Step 1 (201): Provide a hard PCB 23, a CCD component 24 and at least one fixing member 27.

Step 2 (202): Provide a CCD supporting board 25 and a first glue 26. The CCD component 24, CCD supporting board 25, and first glue 26 can be used for producing a CCD module 20 and fixing the CCD module 20 onto a lens assembly (not shown in the figure), and each structure, installation and calibration are the same as described above, and thus will not be described here again.

Step 3 (203): Provide a plurality of hot spray nozzles 56. The fixing member 27 includes a plurality of hot-melt metals 272, and the main board 21 has a plurality of first penetrating holes 213, wherein the hot spray nozzles 56 are corresponsive to the first penetrating holes 213 respectively.

Step 4 (204): Fix the CCD module 20 on the main board 21. The hot spray nozzles 56 spray hot air towards the first penetrating holes 213, such that the first penetrating holes 213 and the first surface 231 are hot-melted and coupled by the hot-melt metals 272 to fix the CCD module 20 onto the main board 21.

Preferably, the fixing members 27 further comprise a plurality of second glues 273, and the main board 21 has a plurality of second penetrating holes 214, and the second glues 273 are provided for binding the second penetrating holes 214 with the first surface 231 of the hard PCB 23 to fix the CCD module 20 with the main board 21 more securely.

In this preferred embodiment, the hard PCB 23 and the fixing member 27 (such as the plurality of hot-melt metals 272 and/or the second glue 273) act as buffers between the CCD component 24 and the main board 21 to reduce possible damages to the CCD component 24 and/or the main board 21. Compared with the CCD module of the first preferred embodiment of the present invention, the CCD module of this preferred embodiment does not require the plurality of positioning pillars, and a hot spray nozzle 56 is used for binding the CCD module to the main board quickly. Therefore, the present invention has the advantages of a simple and quick manufacturing process and a low cost.

What is claimed is:

1. A charge coupled device (CCD) module, fixed between a lens assembly and a main board, and the main board having a first plate surface, and the CCD module comprising:
a hard PCB, having a first surface and a second surface, and the first surface facing the first plate surface;
a CCD component, disposed on the second surface and facing the lens assembly; and
at least one fixing member coupling the hard PCB and the main board;
thereby, the hard PCB and the fixing member act as buffers between the CCD component and the main board.

2. The CCD module of claim 1, wherein the fixing members comprise a plurality of positioning pillars disposed on the first surface.

3. The CCD module of claim 2, wherein the positioning pillars are disposed around the periphery of the first surface.

4. The CCD module of claim 2, wherein the main board comprises a plurality of first penetrating holes corresponding to the positioning pillars respectively, and the positioning pillars are disposed in the first penetrating holes respectively.

5. The CCD module of claim 4, wherein the fixing members further comprise a plurality of hot-melt metals for hot-melting and coupling the positioning pillars to the first penetrating holes respectively.

6. The CCD module of claim 1, further comprising:
a CCD supporting board, disposed on the second surface and having an opening formed thereon for accommodating the CCD component; and
a first glue binding the CCD supporting board with the CCD component.

7. The CCD module of claim 1, wherein the main board comprises a plurality of first penetrating holes, and the fixing members comprise a plurality of hot-melt metals, and the hot-melt metals hot-melt and couple the first penetrating holes and the first surface.

8. The CCD module of claim 7, wherein the main board comprises a plurality of second penetrating holes, and the fixing members further include a plurality of second glues binding the second penetrating hole and the first surface.

9. A manufacturing method of a CCD module, the CCD module being fixed between a lens assembly and a main board, and the main board having a first plate surface, and the manufacturing method comprising the steps of:
providing a hard PCB which has a first surface and a second surface, and the first surface facing the first plate surface;
providing a CCD component which is disposed on the second surface and faces the lens assembly;
providing at least one fixing member which is used for coupling the hard PCB and the main board; and
using the hard PCB and the fixing member as buffers between the CCD component and the main board.

10. The manufacturing method of a CCD module according to claim 9, further comprising the steps of:
providing a lower tool, and the lower tool having a groove for accommodating the hard PCB;
providing an upper tool disposed above the lower tool, and the upper tool having a plurality of through holes, and the fixing member including a plurality of positioning pillars disposed in the plurality of through holes respectively; and
providing a laminating device to press and couple the positioning pillars onto the first surface.

11. The manufacturing method of a CCD module according to claim 10, further comprising the steps of:
providing a CCD supporting board with an opening and disposed on the second surface, and the opening accommodating the CCD component; and
providing a first glue to bind the CCD supporting board and the CCD component.

12. The manufacturing method of a CCD module according to claim 11, further comprising:
calibrating the CCD module on the main board, wherein the fixing members comprise a plurality of hot-melt metals, and the main board has a plurality of first penetrating holes corresponsive to the positioning pillars, and the positioning pillars are disposed in the first penetrating holes respectively.

13. The manufacturing method of a CCD module according to claim 12, further comprising:
fixing the CCD module onto the main board, wherein the positioning pillars and the first penetrating holes are hot-melted and coupled by the plurality of hot-melt metals.

14. The manufacturing method of a CCD module according to claim 9, further comprising:
providing a CCD supporting board with an opening, and the CCD supporting board being disposed on the second surface, and the opening accommodating the CCD component; and
providing a first glue binding the CCD supporting board with the CCD component.

15. The manufacturing method of a CCD module according to claim 14, further comprising:
providing a plurality of hot spray nozzles, and the fixing member including a plurality of hot-melt metals, and the main board having a plurality of first penetrating holes, wherein the hot spray nozzles are corresponsive to the first penetrating holes and spray hot air towards the first penetrating holes respectively, such that the first penetrating holes and the first surface are hot-melted and coupled by the hot-melt metal to fix the CCD module onto the main board.

16. The manufacturing method of a CCD module according to claim 15, wherein the fixing member further comprises a plurality of second glues, and the main board comprises a plurality of second penetrating holes, and the second glues bind the second penetrating holes with the first surface.
